(19) United States
(12) Patent Application Publication
(10) Pub. No.: US 2005/0280481 A1
(43) Pub. Date: Dec. 22, 2005

(54) Wave filter assembly

(76) Inventor: Hsueh-Ming Shih, Taipei (TW)

Correspondence Address: BIRCH STEWART KOLASCH & BIRCH, PO BOX 747, FALLS CHURCH, VA, 22040-0747, US

(21) Appl. No.: 10/870,038

(22) Filed: Jun. 18, 2004

(51) Int. Cl. H03H 7/01

(52) U.S. Cl. 333/181; 333/185

(57) ABSTRACT

The present invention discloses a wave filter assembly which is applicable to large current and comprises a core 20, a first groove base 21, a second groove base 22, a coil 23 and a base 24; wherein the core 20 includes a first axle section 201 and a second axle section 202; the first and second groove bases 21, 22 are disposed at the first and second axle sections 201, 202 respectively; the first and second groove bases 21, 22 are coiled with the coil 23; the base 24 includes an accommodating groove 240 for accommodating the coil 23. With the design of the separate first groove base 21 and second groove base 22, the coiling space is increased, and thus the wave filter assembly of the invention is applicable to large current and has the effect of facilitating the coiling.

### FIELD OF THE INVENTION

The present invention relates to a wave filter assembly, more particularly to a wave filter assembly applicable to large current.

### BACKGROUND OF THE INVENTION

Wave filter is very common and extensively used in computers, televisions and stereo systems, etc. The main function of a wave filter is to prevent electromagnetic interference (EMI) and filter noises. Therefore, the application of wave filters is very important to the current industry, and the structure of a wave filter will be described as follows.

Please refer to FIGS. 1 and 2 for a prior-art wave filter assembly. The traditional wave filter comprises a core 10, two half wire racks 11, a base 12 and a coil 13; wherein the core 10 is substantially n-shaped and comprises a middle axle section 100 transversally disposed at an opening of the core 10 and two wire grooves 110 disposed on the two half wire racks 11, a partition groove 111 disposed between the two wire grooves 110, a coiling gear 112 disposed at an outer side of the half wire rack 11, a semicircular channel 113 disposed in the middle, a recession 120 disposed at the center of a base 12 for accommodating the foregoing wire racks, a positioning groove 121 disposed on both sides of the recession 120 for receiving two sides of the bottom of the core 10, a plurality of short poles 122 extended downwardly from the bottom of the base 12, and a plurality of wire grooves 123 disposed at the periphery of the base 12 for leading out the coil in the wire groove 123 and being connected to the short poles 122. Such prior-art wave filter 1 for preventing electromagnetic interference requires two wire grooves 110 to be disposed on the same coil rack for coiling the wave filter 1. Such arrangement not only makes the coiling more difficult and wastes time and efforts, but also damages the coil 13 (such as an enameled wire) wound around the wire groove 110 easily during the coiling process and results in a short circuit. With the design of the two wire grooves 110, the space for accommodating the coil 13 is smaller, and thus the volume of the coil 13 is limited. The wave filter 1 of this sort is applicable for small current and its power is relatively smaller. The present diversified industry not only requires a high efficiency on the manufacturer's side, but also has a demand on high performance from the consumers. Therefore, the foregoing prior-art wave filter assembly no longer meets the industrial application requirements anymore.

In view of the aforementioned shortcomings of the prior-art wave filter assembly for preventing electromagnetic interference, the inventor of the present invention focused on the related issues to conduct researches and experiments and finally invented the wave filter assembly according to the present invention.

### SUMMARY OF THE INVENTION

The primary objective of the present invention is to solve the foregoing problems and avoid the existing deficiencies by providing a wave filter assembly applicable for large current.

The wave filter assembly in accordance with the present invention comprises:

a core, having a periphery section, a first axle section and a second axle section;

a first groove base, being disposed at the first axle section of the core;

a second groove base being disposed at the second axle section of the core;

a coil, being wound around the first groove base and the second groove base; and

a base, for accommodating the core.

The technical characteristic of the present invention is to increase the coiling space by designing separated first and second groove bases to fit large current and facilitate the coiling.

To make it easier for our examiner to understand the objective of the invention, its structure, innovative features, and performance, we use a preferred embodiment and the attached drawings for the detailed description of the invention.

### BRIEF DESCRIPTION OF THE DRAWINGS

FIG. 1 is an exploded view of a prior-art wave filter assembly.

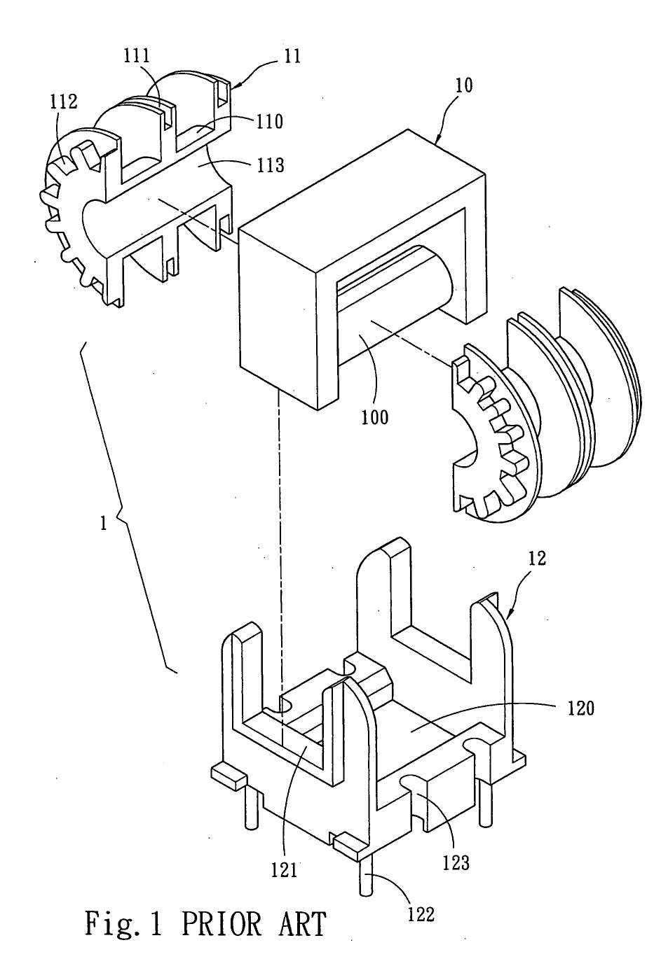

FIG. 2 is a perspective view of a prior-art wave filter assembly.

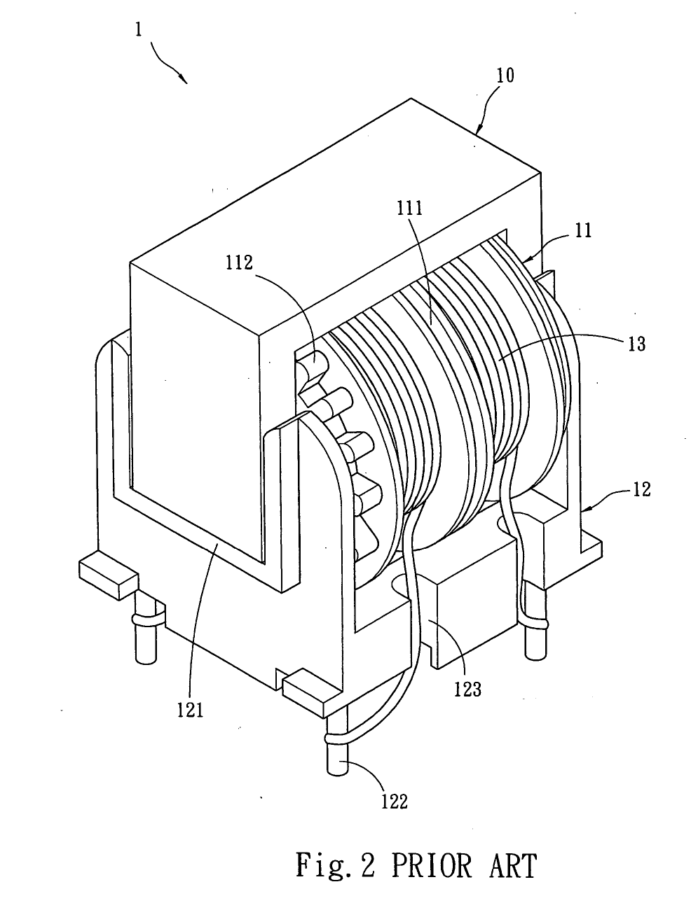

FIG. 3 is an exploded view of the wave filter assembly according to the present invention.

FIG. 4 is a perspective view of the wave filter assembly according to the present invention.

FIG. 5 is an exploded view of the wave filter assembly according to another preferred embodiment of the present invention.

FIG. 6 is a perspective view of the wave filter assembly according to another preferred embodiment of the present invention.

### DETAILED DESCRIPTION OF THE PREFERRED EMBODIMENTS

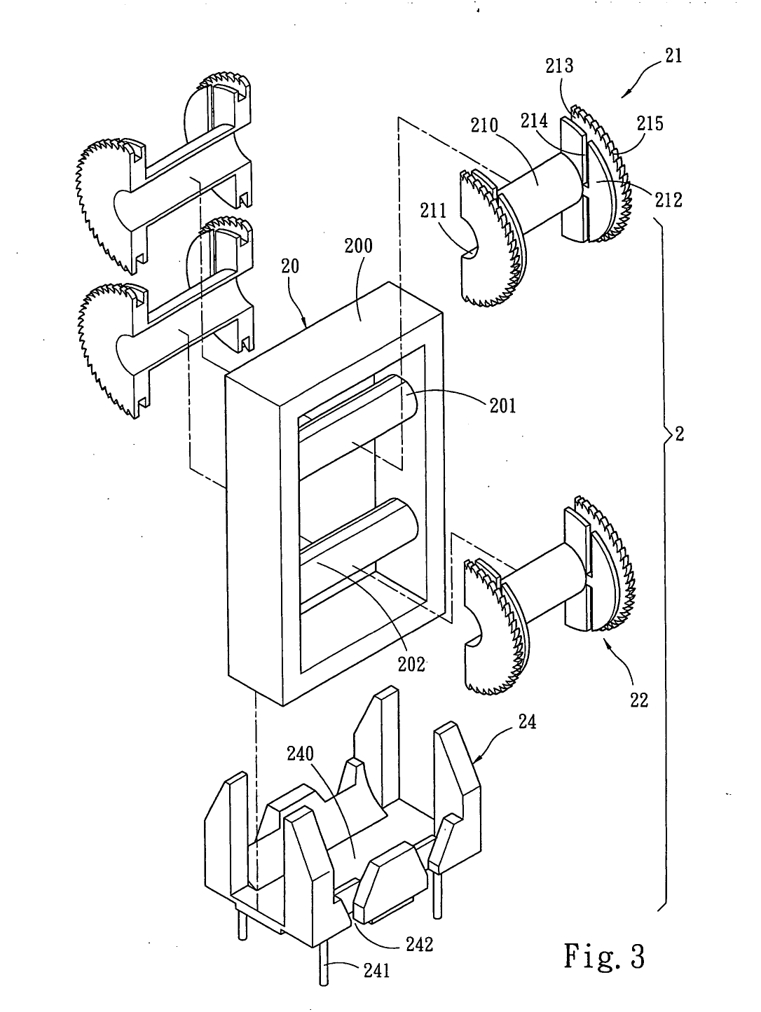

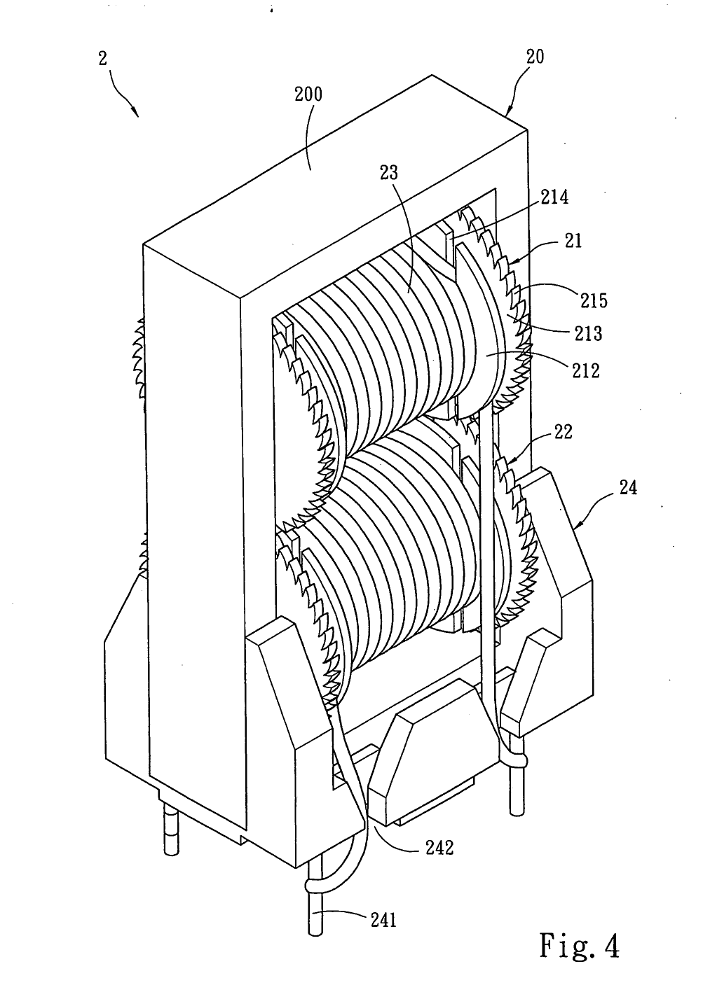

Please refer to FIGS. 3 and 4 for the exploded view and the perspective view of the wave filter assembly of the present invention respectively. The wave filter assembly as shown in the figures comprises a core 20, a first groove base 21, a second groove base 22, a coil 23 and a base 24; wherein the core 20 (which is a magnetic member) comprises a square periphery section 200, a first axle section 201 and a second axle section 202 being parallel with each other and disposed transversally at the first axle section 201 and the second axle section 202, and the first groove base 21 and the second groove base 22 are comprised of two groove racks 210 of the same shape, and the first groove base 21 is disposed in the first axle section 201 of the core 20, and the second groove base 22 is disposed in the second axle section 202 of the core 20. Both the first groove base 21 and the second groove base 22 have a connecting groove 211 for connecting the first axle section 201 and the second axle section 202 of the core 20, and both ends of the first groove base 21 and the second groove base 22 individually have a first circular plate 212 and a second circular plate 213; wherein the first circular plate 212 has an incoming wire groove 214 thereon. Such incoming wire groove 214 is wound around the coil 23, so that the coil 23 hangs on the incoming wire groove 214 to facilitate the coiling and reducing the manufacturing time. Further, the second circular plate 213 at its periphery has a serrated section 215 for winding the coil 23 (which is a flat copper coil wire or enameled wire in this embodiment) around the foregoing first groove base 21 and second groove base 22. The base 24 has an accommodating groove 240 for accommodating the core 20, and the base 24 has four wire connecting poles 241 extended downwardly from the bottom of the base 24 and four wire grooves 242 disposed at the periphery of the base 24 for leading out the foregoing coil 23 and being connected (by soldering) to the wire connecting poles 241.

From the structure of the foregoing wave filter 2, it is obvious that the design of the first axle section 201 and second axle section 202 of the core 20 being disposed in the first groove base 21 and second groove base 22 respectively increases the coiling space of the coil 23. Therefore, a coil 23 with a larger diameter can be used for coiling a wave filter 2. Since the current passing through the coil 23 is directly proportional to the cross-sectional area of the coil 23, therefore such wave filter 2 is applicable for large current (the diameter of the coil can be selected according to the actual need). Further, the design of the separated grooves (the first groove base 21 and the second groove base 22) provides a simple coiling procedure so that the operator at the assembly line will not mix up the coiling and thus reducing the time and simplifying the manufacturing procedure. Further, the flat copper foil wire used for the coil 23 not only gives an artistic look to the wave filter assembly, but also increases the cross-sectional area of the coil 23. The present invention is thus applicable for large current and large power. The number of coils can be reduced as well, and thus providing the advantages of simplifying the coiling procedure and eliminating the wastage of power. The present invention is definitely useful for the industry.

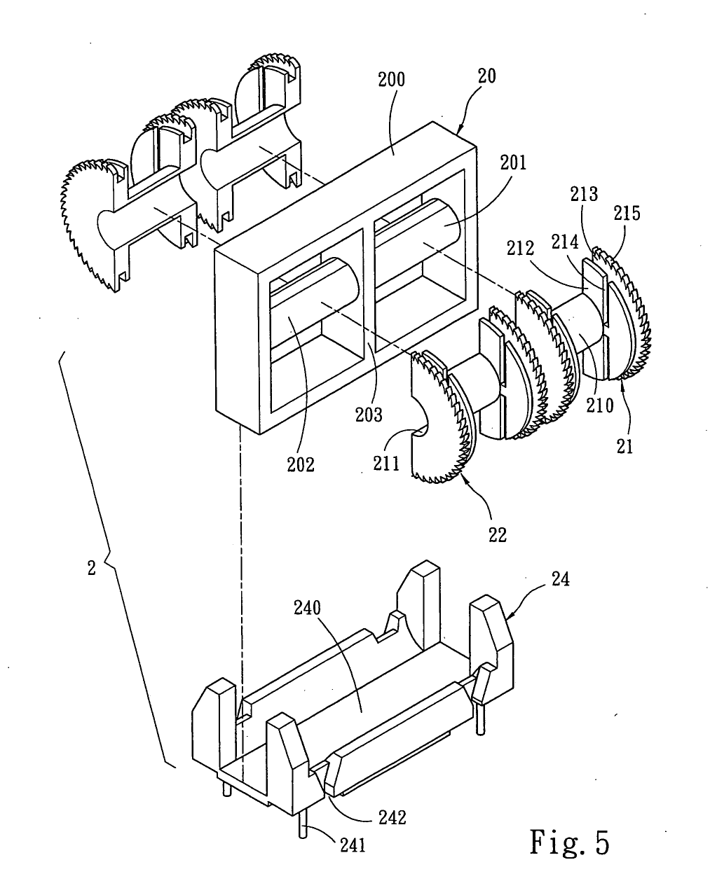

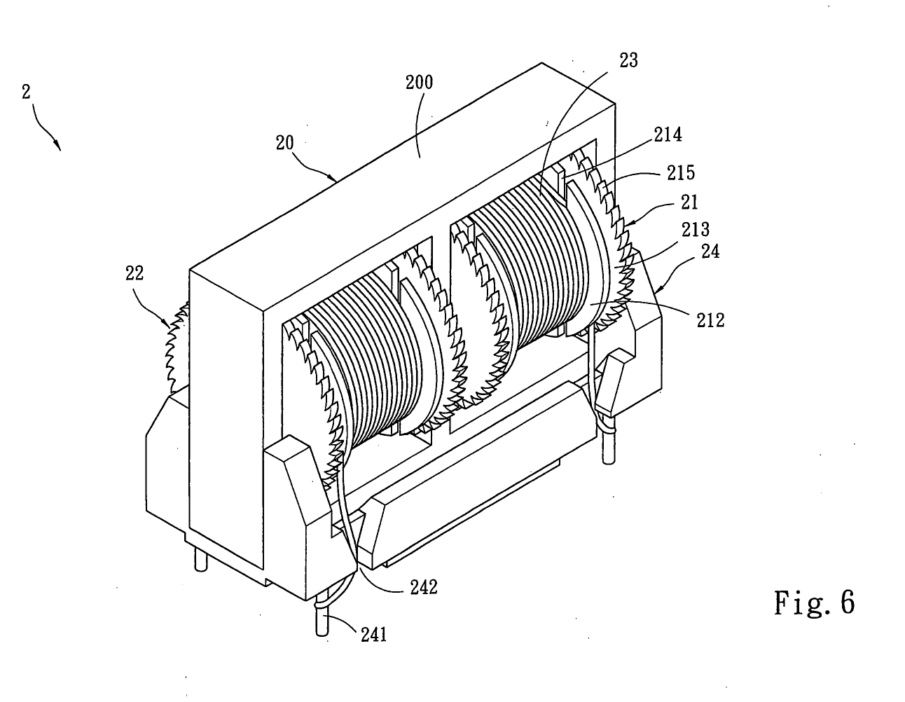

Please refer to FIGS. 5 and 6 for the exploded view and the perspective view of the wave filter assembly according to another preferred embodiment of the present invention. The wave filter assembly as shown in the figures comprises a core 20, a first groove base 21, a second groove base 22, a coil 23 and a base 24; wherein the core 20 (which is a magnetic member) comprises a square periphery section 200, a first axle section 201 and a second axle section 202 being disposed transversally at the first axle section 201 and the second axle section 202, and a partition 203 being disposed between the first axle section 201 and the second axle section 202 for isolating the first axle section 201 and the second axle section 202; the first groove base 21 and the second groove base 22 are comprised of two groove racks 210 of the same shape, and the first groove base 21 is disposed in the first axle section 201 of the core 20, and the second groove base 22 is disposed in the second axle section 202 of the core 20. Both the first groove base 21 and the second groove base 22 have a connecting groove 211 for connecting the first axle section 201 and the second axle section 202 of the core 20, and both ends of the first groove base 21 and the second groove base 22 individually have a first circular plate 212 and a second circular plate 213; wherein the first circular plate 212 has an incoming wire groove 214 thereon. Such incoming wire groove 214 is wound around the coil 23, such that the coil 23 hangs on the incoming wire groove 214 to facilitate the coiling and reducing the manufacturing time.

The coil 23 (which is a flat copper coil wire or an enameled wire in this embodiment) is wound around the foregoing first groove base 21 and second groove base 22. The base 24 has an accommodating groove 240 for accommodating the core 20, and the base 24 has four wire connecting poles 241 extended downwardly from the bottom of the base 24 and four wire grooves 242 disposed at the periphery of the base 24 for leading out the foregoing coil 23 and being connected (by soldering) to the wire connecting poles 241. With the design of the separated first groove base 21 and second groove base 22, the coiling space is increased, and the present invention is thus applicable for large current and has the effect of facilitates the coiling.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

1. A wave filter assembly applicable to large current, comprising:
a core 20, having a square periphery section 200, and said periphery section 200 comprising a first axle section 201 and a second axle section 202 therein;
a first groove base 21, being comprised of two groove racks 210 of the same shape for accommodating said first axle section 201 of said core 20;
a second groove base 22, being comprised of two groove racks 210 of the same shape for accommodating said second axle section 202 of said core 20;
a coil 23, being coiled around said first and second groove bases 21, 22; and
a base 24, having an accommodating groove 240 for accommodating said core 20.

2. The wave filter assembly of claim 1, wherein said core 20 has a partition 203 disposed between said first axle section 201 and said second axle section 202.

3. The wave filter assembly of claim 1, wherein said first and second groove bases 21, 22 individually have two circular plates 212, 213 at each of both ends, and one of said circular plates 212, 213 has an incoming wire groove 214, and said incoming wire groove 214 winds around said coil 23 by hanging said coil 23 onto said incoming wire groove 214 to facilitate the coiling and reduce the manufacturing time.

4. The wave filter assembly of claim 1, wherein said coil 23 is a flat copper foil wire.

5. The wave filter assembly of claim 1, wherein said coil 23 is an enameled wire.

6. The wave filter assembly of claim 1, wherein said base 24 comprises a plurality of downwardly extended wire connecting poles 241 being disposed at the side of the bottom of said base 24 and wounded by a plurality of wire grooves 242 for leading out said coil 23 and being coupled to said wire connecting pole 241.
